(19) United States
(12) Patent Application Publication
(10) Pub. No.: US 2014/0347064 A1
(43) Pub. Date: Nov. 27, 2014

(54) DEVICE FOR TESTING FAN

(71) Applicants: HONG FU JIN PRECISION INDUSTRY (ShenZhen) CO., LTD., Shenzhen (CN); HON HAI PRECISION INDUSTRY CO., LTD., New Taipei (TW)

(72) Inventors: KANG WU, Shenzhen (CN); BO TIAN, Shenzhen (CN)

(73) Assignees: HONG FU JIN PRECISION INDUSTRY (ShenZhen) CO., LTD., Shenzhen (CN); HON HAI PRECISION INDUSTRY CO., LTD., New Taipei (TW)

(21) Appl. No.: 14/284,505

(22) Filed: May 22, 2014

(30) Foreign Application Priority Data
May 24, 2013 (CN) 2013101986583

(51) Int. Cl. G01R 31/02

(52) U.S. Cl. CPC G01R 31/02
USPC 324/511

(57) ABSTRACT

A fan testing device connects to the fan and a motherboard. The fan testing device includes a first connection module, a second connection module, a control chip, and an alarm module. The control chip is coupled to signal pins of the first and second connectors. The control chip outputs different signals to control the alarm module according to the connections of the first and second connection modules.

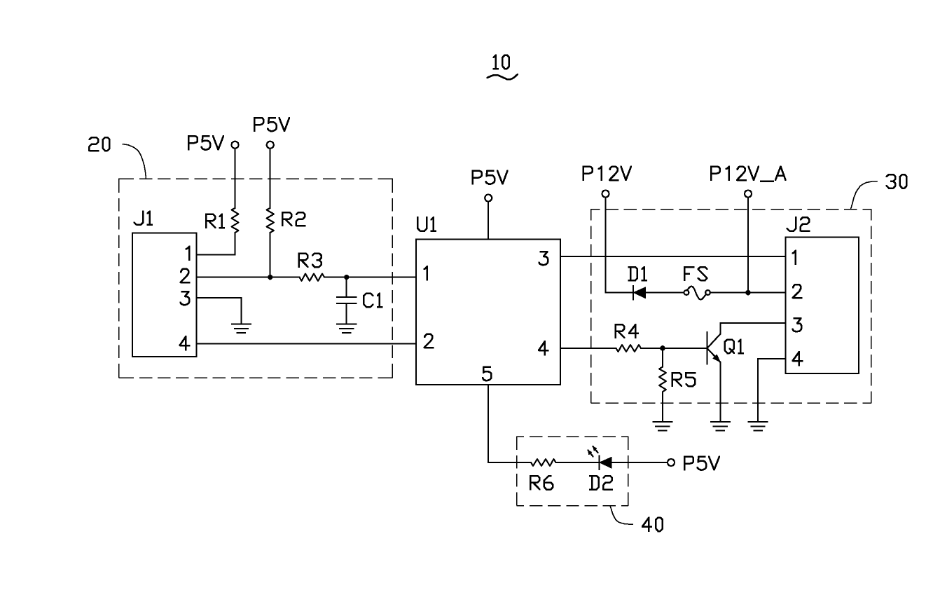

### FIELD

The present disclosure relates to a fan testing device.

### BACKGROUND

A fan testing device has a first connector to connect to a motherboard, and a second connector to connect to a fan.

### BRIEF DESCRIPTION OF THE DRAWING

Many aspects of the present disclosure can be better understood with reference to the following drawing. The components in the drawing are not necessarily drawn to scale, the emphasis instead being placed upon clearly illustrating the principles of the present disclosure.

The FIGURE is a circuit diagram of an embodiment of a fan testing device of the present disclosure.

### DETAILED DESCRIPTION

It will be appreciated that for simplicity and clarity of illustration, where appropriate, reference numerals have been repeated to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawing is not necessarily to scale and the proportions of certain parts have been exaggerated to better illustrate details and features of the present disclosure.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series, and the like.

The FIGURE shows an embodiment of a fan test device 10 of the present disclosure.

The fan test device 10 can comprise a first connection module 20 to connect to a fan, a second connection module 30 to connect to a motherboard, a control chip U1, and an alarm module 40. In the embodiment, the fan test device 10 can notify a user whether the first connection module 20 and the second connection module 30 are coupled incorrectly to the motherboard and the fan, respectively.

The first connection module 20 can comprise a first connector J1, a first resistor R1, a second resistor R2, a third resistor R3, and a capacitor C1. The first connector J1 can be coupled to the fan. A power pin 1 of the first connector J1 is coupled to a first power input terminal P5V through the first resistor R1. A speed pin 2 of the first connector J1 is coupled to the first power input terminal P5V through the second resistor R2. The speed pin 2 of the first connector J1 is also grounded through the third resistor and the capacitor C1 in that order. A node between the third resistor R3 and the capacitor C1 is coupled to a speed pin 1 of the control chip U1. A ground pin 3 of the first connector J1 is grounded. A signal pin 4 of the first connector J1 is coupled to a control pin 2 of the control chip U1. The signal pin 4 of the first connector J1 is further coupled to a power source (not shown) that outputs a constant high-level signal, such as logic 1, to the signal pin 4 of the first connector J1.

The second connection module 30 can comprise a second connector J2, a fourth resistor R4, a fifth resistor R5, a diode D1, a fuse FS, and an electronic switch Q1. The second connector J2 can be coupled to the motherboard. A signal pin 1 of the second connector J2 is coupled to a signal pin 3 of the control chip U1. A power pin 2 of the second connector J2 is coupled to a second power input terminal P12V_A. The power pin 2 of the second connector J2 is also coupled to an anode of the diode D1 through the fuse FS. A cathode of the diode D1 is coupled to a third power input terminal P12V. An alarm pin 3 of the second connector J2 is coupled to a second terminal of the electronic switch Q1. A first terminal of the electronic switch Q1 is grounded through the fifth resistor R5. The first terminal of the electronic switch Q1 is also coupled to an alarm pin 4 of the control chip U1 through the fourth resistor R4. A third terminal of the electronic switch Q1 is grounded. A ground pin 4 of the second connector J2 is grounded.

The alarm module 40 can comprise a sixth resistor R6 and a light-emitting diode (LED) D2. A cathode of the LED D2 is coupled to an indicating pin 5 of the control chip U1 through the sixth resistor R6. An anode of the LED D2 is coupled to the first power input terminal PSV.

When the first connector J1 is coupled to the motherboard while the second connector J2 is coupled to the fan, the signal pin 4 of the first connector J1 is coupled to ground of the motherboard, causing the signal pin 4 of the first connector J1 to be grounded, and further causing the control pin 2 of the control chip U1 to be at a low level. The signal pin 1 of the second connector J2 is coupled to the fan, causing the signal pin 1 of the second connector J2 to be at a low level and further causing the signal pin 3 of the control chip U1 to be at a low level.

The alarm module 40 alerts when the alarm module 40 receives a first signal from the control chip U1. In the embodiment, the control chip U1 outputs a low-level signal, such as logic 0, through the indicating pin 5 when the control pin 2 and the signal pin 3 of the control chip U1 are both at a low level, causing the LED D2 to light up to indicate that the connection between the first connector J1 and the motherboard, and the connection between the second connector J2 and the fan, are incorrect.

When the first connector J1 is coupled to the fan while the second connector J2 is coupled to the motherboard, the motherboard outputs a high-level signal to the signal pin 1 of the second connector J2, causing the signal pin 3 of the control chip U1 to be at a high level. The control pin 2 of the control chip U1 receives the constant high-level signal from the signal pin 4 of the first connector J1. The control chip U1 outputs a high-level signal through the indicating pin 5 when the control pin 2 and the signal pin 3 of the control chip U1 are both at a high level, causing the LED D2 to turn off. The fan outputs a speed signal through the speed pin 2 of the first connector J1, and the control chip U1 receives the speed signal through the speed pin 1 of the control chip U1. When the control chip U1 determines that a speed of the fan is abnormal, the control chip U1 outputs a high-level signal to the first terminal of the electronic switch Q1 through the alarm pin 4 of the control chip U1, causing the electronic switch Q1 to turn on. When the electronic switch Q1 is turned on, the alarm pin 3 of the second connector J2 is grounded. When the alarm pin 3 of the second connector J2 is grounded, the motherboard receives a low-level signal from the alarm pin 3 of the second connector J2 and determines that the speed of the fan is abnormal. When the control chip U1 determines that the speed of the fan is normal, the control chip U1 outputs a low-level signal to the first terminal of the electronic switch Q1, causing the electronic switch Q1 to turn off. The motherboard receives a high level signal through the alarm pin 3 of the second connector J2 and determines that the speed of the fan is normal.

In the embodiment, the electronic switch Q1 is an NPN transistor, but can be any other suitable transistor.

The fan test device 10 operates normally when the first connector J1 is coupled to the fan, and the second connector J2 is coupled to the motherboard, and notifies a user when the first connector J1 and the second connector J2 are coupled to the motherboard and the fan, respectively.

While the disclosure has been described by way of examples, it is to be understood that the disclosure is not limited thereto. To the contrary, it is intended to cover various modifications and similar arrangements as would be apparent to those skilled in the art. Therefore, the range of the appended claims should be accorded the broadest interpretation so as to encompass all such modifications and similar arrangements.

What is claimed is:

1. A fan test device coupled between a motherboard and a fan, the fan test device comprising:
a first connection module comprising a first connector to connect the fan, wherein the first connector comprises a signal pin, the fan test device outputs a high level signal through the signal pin of the first connector, when the first connector is coupled to the fan, the signal pin of the first connector is at a high level, when the first connector is coupled to the motherboard, the signal pin of the first connector is grounded and at a low level;
a second connection module comprising a second connector to connect the motherboard, wherein the second connector comprises a signal pin, the motherboard outputs a high level signal to the signal pin of the second connector when the second connector is coupled to the motherboard, and the signal pin of the second connector is at a low level when the second connector is coupled to the fan;
a control chip, wherein the control chip is coupled between the first connector and the second connector, when the first connector is coupled to the motherboard and the second connector is coupled to the fan, the control chip receives low level signals from the signal pin of the first connector and the signal pin of the second connector, the control chip outputs a first signal through an indicating pin, when the first connector is coupled to the fan and the second connector is coupled to the motherboard, the control chip receives high level signals from the signal pin of the first connector and the signal pin of the second connector, the control chip outputs a second signal through the indicating pin; and
an alarm module, wherein the alarm module alerts when the alarm module receives the first signal from the control chip.

2. The fan test device of claim 1, wherein the first connection module comprises a first resistor, a second resistor, a third resistor, and a capacitor, a power pin of the first connector is coupled to a first power input terminal through the first resistor, a speed pin of the first connector is coupled to the first power input terminal through the second resistor, the speed pin of the first connector is grounded through the third resistor and the capacitor in that order, a node between the third resistor and the capacitor is coupled to a speed pin of the control chip, a ground pin of the first connector is grounded, and the signal pin of the first connector is coupled to a control pin of the control chip.

3. The fan test device of claim 2, wherein the second connection module comprises a fourth resistor, a fifth resistor, a diode, a fuse, and an electronic switch, the signal pin of the second connector is coupled to a signal pin of the control chip, a power pin of the second connector is coupled to a second power input terminal, the power pin of the second connector is coupled to an anode of the diode through the fuse, a cathode of the diode is coupled to a third power input terminal, an alarm pin of the second connector is coupled to a second terminal of the electronic switch, a first terminal of the electronic switch is grounded, the first terminal of the electronic switch is coupled to an alarm pin of the control chip through the fourth resistor, a third terminal of the electronic switch is grounded, and a ground pin of the second connector is grounded.

4. The fan test device of claim 1, wherein the alarm module comprises a sixth resistor and a light emit diode (LED), a cathode of the LED is coupled to the first power input terminal, and an anode of the LED is coupled to the indicating pin of the control pin through the sixth resistor.
